(19) United States
(12) Patent Application Publication
(10) Pub. No.: US 2024/0367979 A1
(43) Pub. Date: Nov. 7, 2024

(54) A NONCOVALENT HYBRID COMPRISING CARBON NANOTUBES (CNT) AND AROMATIC COMPOUNDS AND USES THEREOF

(71) Applicant: YEDA RESEARCH AND DEVELOPMENT CO. LTD., Rehovot (IL)

(72) Inventors: Boris RYBTCHINSKI, Givaataim (IL); Haim WEISSMAN, Rehovot (IL); Lior SNARSKI, Rehovot (IL); Margarita GALPER, Rehovot (IL)

(73) Assignee: YEDA RESEARCH AND DEVELOPMENT CO. LTD., Rehovot (IL)

(21) Appl. No.: 18/262,732

(22) PCT Filed: Feb. 3, 2022
(86) PCT No.: PCT/IL2022/050147

§ 371 Date: Jul. 25, 2023

(30) Foreign Application Priority Data
Feb. 3, 2021 (IL) 280607

(51) Int. Cl. C01B 32/174; B01D 17/02; B82Y 30/00; B82Y 40/00; C01B 32/159; C02F 1/28; C02F 101/32; C08K 9/04; C09D 5/03; C09D 5/24; C09D 7/62; G01N 27/30; H01G 11/26; H01G 11/36; H01M 4/62; H05K 9/00

(52) U.S. Cl. CPC C01B 32/174; B01D 17/0202; C01B 32/159; C02F 1/288; C09D 5/035; C09D 5/24; C09D 7/62; G01N 27/304; G01N 27/308; H01M 4/625; H05K 9/0083; B82Y 30/00; B82Y 40/00; C01B 2202/02; C01B 2202/06; C01B 2202/22; C02F 1/283; C02F 1/285; C02F 2101/32; C08K 9/04; C08K 2201/001; C08K 2201/011; H01G 11/26; H01G 11/36

(57) ABSTRACT

Provided herein noncovalent hybrids comprising carbon nanotubes (CNTs) and aromatic compounds, composites based on them, process of preparation and uses thereof; wherein the hybrids possess superior mechanical and electrical properties.

### FIELD OF THE INVENTION

This invention provides noncovalent hybrids comprising carbon nanotubes (CNTs) and aromatic compounds, composites based on them, process of preparation and uses thereof; wherein the hybrids possess superior mechanical and electrical properties and provide dispersible CNT hybrids in organic and aqueous solvents.

### BACKGROUND OF THE INVENTION

CNTs are used to produce high quality electrodes and can enhance properties of various materials (e.g. polymers).¹ CNTs, both multiwalled (MWCNTs) and single walled (SWCNTs) become readily available and inexpensive due to recent large-scale production. Yet, CNTs have a high tendency for bundling, which impedes their dispersion in liquid (solvents) and solid (polymer) media. This issue limits the ability to fabricate materials with improved properties conveniently and cost-efficiently. This issue is a central challenge in the field.²⁻⁶

In the past the inventors used perylene diimide derivatives for CNT dispersions in solution⁷⁻¹¹, however, dispersion at concentration above 0.2 g/l could not be obtained in neat water, and in most organic solvents.

There is a need for new preferred solvent dispersed CNTs to better use it in spray-coating, filtration, casting and bulk composite applications.

### REFERENCES

(1) De Volder, M. F. L.; Tawfick, S. H.; Baughman, R. H.; Hart, a. J. Carbon nanotubes: present and future commercial applications. Science (New York, N.Y.) 2013, 535-539.
(2) Ata, M. S.; Poon, R.; Syed, A. M.; Milne, J.; Zhitomirsky, I. New developments in non-covalent surface modification, dispersion and electrophoretic deposition of carbon nanotubes. Carbon 2018, 130, 584-598.
(3) Di Crescenzo, A.; Ettorre, V.; Fontana, A. Non-covalent and reversible functionalization of carbon nanotubes. Beilstein J Nanotechnol 2014, 5, 1675-1690.
(4) Kharissova, O. V.; Kharisov, B. I.; de Casas Ortiz, E. G. Dispersion of carbon nanotubes in water and non-aqueous solvents. RSC Advances 2013, 3, 24812-24852.
(5) Koh, B.; Kim, G.; Yoon, H. K.; Park, J. B.; Kopelman, R.; Cheng, W. Fluorophore and Dye-Assisted Dispersion of Carbon Nanotubes in Aqueous Solution. Langmuir 2012, 28, 11676-11686.
(6) Liang. L.; Xie, W.; Fang, S.; He, F.; Yin, B.; Tlili, C.; Wang, D.; Qiu, S.; Li, Q. High-efficiency dispersion and sorting of single-walled carbon nanotubes via non-covalent interactions. J Mater Chem C 2017. 5, 11339-11368.
(7) Eisenberg. O.; Algavi, Y. M.; Weissman, H.; Narevicius, J.; Rybtchinski, B.; Lahav, M.; Boom, M. E. Dual Function Metallo-Organic Assemblies for Electrochromic-Hybrid Supercapacitors. Advanced Materials Interfaces 2020, 7.
(8) Niazov-Elkan, A.; Weissman, H.; Dutta, S.; Cohen, S. R.; Iron, M. A.; Pinkas, I.; Bendikov, T.; Rybtchinski, B. Self-Assembled Hybrid Materials Based on Organic Nanocrystals and Carbon Nanotubes. Adv Mater 2018, 30.
(9) Siram, R. B. K.; Khenkin, M. V.; Niazov-Elkan, A.; K, M. A.; Weissman, H.; Katz, E. A.; Visoly-Fisher, I.; Rybtchinski, B. Hybrid organic nanocrystal/carbon nanotube film electrodes for air-and photo-stable perovskite photovoltaics. Nanoscale 2019, 11, 3733-3740.
(10) Tsarfati, Y.; Strauss, V.; Kuhri, S.; Krieg, E.; Weissman, H.; Shimoni, E.; Baram, J.; Guldi, D. M.; Rybtchinski, B. Dispersing perylene diimide/SWCNT hybrids: structural insights at the molecular level and fabricating advanced materials. J Am Chem Soc 2015, 137, 7429-7440.
(11) Yanshyna, O.; Weissman, H.; Rybtchinski, B. Recyclable electrochemical supercapacitors based on carbon nanotubes and organic nanocrystals. Nanoscale 2020, 12, 8909-8914.

### SUMMARY OF THE INVENTION

In one embodiment, this invention provides a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein their salts thereof and their derivative thereof.

In some embodiments, provided herein a noncovalent hybrid consisting essentially of a single-walled carbon nanotube (CNT) and at least one aromatic compound, wherein the aromatic compound is selected from the group consisting of anthraquinone, acridine, caffeic acid, phenazine, thymolphthalein, aramid nanofiber, their salt thereof and their derivative thereof.

A noncovalent hybrid consisting essentially of a multi-walled carbon nanotube (CNT) and at least one aromatic compound, wherein the aromatic compound is selected from the group consisting of anthraquinone, caffeic acid, safranin, thymolphthalein, aramid nanofiber, their salt thereof and their derivative thereof.

In one embodiment, this invention provides a composite comprising a polymer and a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofiber (ANF), their salts thereof and their derivative thereof, wherein the composite has improved mechanical and/or conductivity. In other embodiments, the carbon nanotube is a single-walled carbon nanotube. In other embodiments, the carbon nanotube is a multi-walled carbon nanotube.

In one embodiment, this invention provides a porous electrode for electrochemical application, comprising a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofiber (ANF). their salts thereof and their derivative thereof. In other embodiments, the carbon nanotube is a single-walled carbon nanotube. In other embodiments, the carbon nanotube is a multi-walled carbon nanotube.

In one embodiment, this invention provides a stretchable, flexible and/or inflatable material comprising a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofiber (ANF), their salts thereof and their derivative thereof, wherein the hybrid is conductive, and the conductivity is maintained upon stretching or inflation of the material. In other embodiments, the carbon nanotube is a single-walled carbon nanotube. In other embodiments, the carbon nanotube is a multi-walled carbon nanotube.

In one embodiment, this invention provides an EMI (electromagnetic interference) shielding and electromagnetic radiation absorbers comprising a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofiber (ANF), their salts thereof and their derivative thereof, wherein the hybrid is conductive in the infrared and microwave ranges. In other embodiments, the carbon nanotube is a single-walled carbon nanotube. In other embodiments, the carbon nanotube is a multi-walled carbon nanotube.

In one embodiment, this invention provides a construction material comprising a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofiber, their salts thereof and their derivative thereof, wherein the hybrid reinforces the construction material. In other embodiments, the carbon nanotube is a single-walled carbon nanotube. In other embodiments, the carbon nanotube is a multi-walled carbon nanotube.

In one embodiment, this invention provides a process for the preparation of a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofiber. their salts thereof and their derivative thereof; wherein the process comprises:
optionally grinding the carbon nanotube; and
mixing the carbon nanotube and the at least one aromatic compound in a sonication bath in an aqueous solvent, an organic solvent, or combination thereof and sonicated for a period of time to obtain a dispersion comprising the hybrid.

### BRIEF DESCRIPTION OF THE FIGURES

The subject matter regarded as the present invention is particularly pointed out and distinctly claimed in the concluding portion of the specification. The present invention, however, both as to organization and method of operation, together with objects, features, and advantages thereof, may best be understood by reference to the following detailed description when read with the accompanying drawings in which:

FIGS. 1A-1C: (FIG. 1A) presents a SEM image of a polyethylene (PE) sheet covered from both sides with a SWCNT-alizarin hybrid as described in Example 2; (FIG. 1B) SEM image of the cross-section of the same sheet illustrating the double sided coating; (FIG. 1C) zoom-in on the area in the dashed-line rectangle in (FIG. 1B). Illustrating the PE-SWCNT-alizarin composite with a thickness of 93-103 μm and the layers of the SWCNT-alizarin hybrid with an average thickness of 10±3 μm.

FIGS. 2A-2E present a picture of dispersions in different organic solvents before and after bath sonication, demonstrating a more homogeneous dispersion and more stable, following the sonication step: (FIG. 2A) MWCNT in ACN, left blank and right with purpurin prior 15 min bath sonication; (FIGS. 2B-2E) MWCNT in different solvents, right blank and left with purpurin after 14 h after bath sonication (FIG. 2B) ACN; (FIG. 2C) acetone; (FIG. 2D) EA; (FIG. 2E) THF.

FIGS. 3A-3E present (FIG. 3A) a SEM image of a non-woven polypropylene (PP) sheet covered from one side with a SWCNT-alizarin hybrid; (FIG. 3B) SEM image of the cross-section of the same sheet illustrating also the coating of the internal PP fibers with up to several hundreds of nm of the SWCNT hybrid; (FIG. 3C) A zoom-in on a cross-sectioned PP fiber and its SWCNT hybrid coating; (FIG. 3D) A zoom-in on the area in the dashed-line rectangle in (FIG. 3C); (FIG. 3E) A zoom-in on the area in the dashed-line rectangle in FIG. 3D.

It will be appreciated that for simplicity and clarity of illustration, elements shown in the figures have not necessarily been drawn to scale. For example, the dimensions of some of the clements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The superior mechanical and electrical properties of carbon nanotubes (CNTs) are uniquely advantageous for enhancing mechanical and electrical properties of composites (e.g. polymer/CNT ones) that have a broad applicability as electrodes, reinforced materials, antistatic/EMI shielding materials, and construction materials. Noncovalent molecular attachment to carbon nanotubes (CNTs) has become a preferred approach for overcoming the dominant tendency of CNTs for aggregation, without harming CNT mechanical and electrical properties (as typical of covalent modifications). This invention provides a hybrid of inexpensive aromatic molecules and CNTs which noncovalently modify CNTs for efficient and stable dispersions in a broad variety of solvents, solvent mixtures and polymers. The resulting CNT materials can be utilized for the fabrication of electrodes, sensors, and composites with improved mechanical and electrical properties.

### Noncovalent Hybrid

In some embodiments, the invention is directed to noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofiber, their salts thereof and their derivative thereof.

In some embodiments, the hybrid provided herein comprises a carbon nanotube (CNT) and anthraquinone, salt thereof or derivatives thereof. In another embodiment, the anthraquinone and derivative thereof is represented by the structure of formula I:

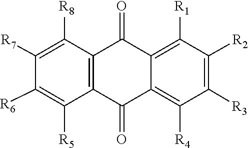

wherein each of R₁-R₈ is independently hydrogen, hydroxy, alkyl, alkenyl, halide, haloalkyl, CN, COOH, alkyl-COOH, alkylamine, amide, alkylamide, aryl, heteroaryl, cycloalkyl, heterocycloalkyl, thio (SH), thioalkyl, alkoxy, ether (alkyl-O-alkyl), OR⁹, COR⁹, COOCOR⁹, COOR⁹, OCOR⁹, OCONHR⁹, NHCOOR⁹, NHCONHR⁹, OCOOR⁹, CON(R⁹)₂, SR⁹, SO₂R⁹, SOR⁹SO₂NH₂, SO₂NH(R⁹)₂, SO₂N(R⁹)₂, NH₂. NH(R⁹), N(R⁹)₂, CONH₂, CONH(R⁹), CON(R⁹)₂, CO(N-heterocycle), NO₂, cyanate, isocyanate, thiocyanate, isothiocyanate, mesylate, tosylate or triflate; wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. Each represents a separate embodiment of this invention. In other embodiments, the carbon nanotube is a single-walled carbon nanotube.

In other embodiments, the carbon nanotube is a multi-walled carbon nanotube. In some embodiments, R₁, R₂, R₃, R₄, R₅, R₆, R₇ or R₈ of the structure of formula I is each independently a hydrogen. In some embodiments, R₁, R₂, R₃, R₄, R₅, R₆, R₇ or R₈ is each independently hydroxy. In some embodiments, R₁, R₂, R₃, R₄, R₅, R₆, R₇or R₈ is each independently an alkyl. In some embodiments, R₁, R₂, R₃, R₄, R₅, R₆, R₇or R₈is each independently an alkenyl. In some embodiments, R₁, R₂, R₃, R₄, R₅, R₆, R₇or R₈ is each independently a halide. In some embodiments, R₁, R₂, R₃, R₄, R₅, R₆, R₇or R₈ is each independently a haloalkyl. In some embodiments, R₁, R₂, R₃, R₄, R₅, R₆, R₇or R₈ is each independently a CN. In some embodiments, R₁, R₂, R₃, R₄, R₅, R₆, R₇or R₈ is each independently a COOH. In some embodiments, R₁, R₂, R₃, R₄, R₅, R₆, R₇or R₈ is each independently a alkyl-COOH. In some embodiments, R₁, R₂, R₃, R₄, R₅, R₆, R₇or R₈is each independently an alkylamine. In some embodiments, R₁, R₂, R₃, R₄, R₅, R₆, R₇or R₈is each independently an amide. In some embodiments, R₁, R₂, R₃, R₄, R₅, R₆, R₇or R₈is each independently an aryl, In some embodiments, R₁, R₂, R₃, R₄, R₅, R₆, R₇ or R₈ is each independently a heteroaryl. In some embodiments, R₁, R₂, R₃, R₄, R₅, R₆, R₇ or R₈ are each independently a cycloalkyl. In some embodiments, R₁, R₂, R₃, R₄, R₅, R₆, R₇ or R₈is each independently a heterocycloalkyl. In some embodiments, R₁, R₂, R₃, R₄, R₅, R₆, R₇ or R₈ is each independently a haloalkyl. In some embodiments, R₁, R₂, R₃, R₄, R₅, R₆, R₇or R₈ is each independently a thio (SH). In some embodiments, R₁, R₂, R₃, R₄, R₅, R₆, R₇or R₈ is each independently a thioalkyl. In some embodiments, R₁, R₂, R₃, R₄, R₅, R₆, R₇or R₈ is each independently an alkoxy. In some embodiments, R₁, R₂, R₃, R₄, R₅, R₆, R₇or R₈is each independently an ether (alkyl-O-alkyl). In some embodiments, R₁, R₂, R₃, R₄, R₅, R₆, R₇or R₈ is each independently a OR⁹, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ are each independently a COR⁹, wherein R⁹ is H, (C₁-C₁₀) alkyl, (C₁-C₁₀) haloalkyl, (C₃-C₈)cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ are each independently a COOCOR⁹, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ are each independently a COOR⁹, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ is each independently a OCOR⁹, wherein R⁹ is H, (C₁-C₁₀)alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ is each independently a OCONHR⁹, wherein R⁹ is H, (C₁-C₁₀) alkyl, (C₁-C₁₀)haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ is each independently a NHCOOR⁹, wherein R⁹ is H, (C₁-C₁₀)alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ is each independently a NHCONHR⁹, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ is each independently a OCOOR⁹, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇or R₈ is each independently a CON(R⁹)₂, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ is each independently a SR⁹, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇or R₈is each independently a SO₂R⁹, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇ or R₈ is cach independently a SOR⁹, wherein R⁹ is H, (C₁-C₁₀) alkyl, (C₁-C₁₀) haloalkyl, (C₃-C₈)cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇or R₈ is cach independently a SO₂NH₂. In some embodiments, R₁, R₂, R₃, R₄, R₅, R₆, R₇or R₈are each independently a SO₂NH(R⁹), wherein R⁹ is H, (C₁-C₁₀)alkyl, (C₁-C₁₀)haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇or R₈ is each independently a SO₂N(R⁹)₂, wherein R⁹ is H, (C₁-C₁₀)alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇or R₈ is each independently a NH₂. In some embodiments, R₁, R₂, R₃, R₄, R₅, R₆, R₇ or R₈ are each independently a NH(R⁹), wherein R⁹ is H, (C₁-C₁₀) alkyl, (C₁-C₁₀) haloalkyl, (C₃-C₈)cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇or R₈ are each independently a N(R⁹)₂, wherein R⁹ is H, (C₁-C₁₀) alkyl, (C₁-C₁₀) haloalkyl, (C₃-C₈) cycloalkyl, aryl or heteroaryl, wherein the alkyl, haloalkyl, cycloalkyl, aryl or heteroaryl groups are optionally substituted. In some embodiments, R₁, R₂, R₃, R₄, R₅, R₆, R₇or R₈ is each independently a CONH₂. In some embodiments, R₁, R₂, R₃, R₄, R₅, R₆, R₇or R₈is each independently a haloalkyl CONH(R⁹). In some embodiments, R₁, R₂, R₃, R₄, R₅, R₆, R₇or R₈is each independently a CON(R⁹)₂. In some embodiments, R₁, R₂, R₃, R₄, R₅, R₆, R₇or R⁸ is each independently a CO (N-heterocycle). In some embodiments, R₁, R₂, R₃, R₄, R₅, R₆, R₇or R₈ is each independently a NO₂. In some embodiments, R₁, R₂, R₃, R₄, R₅, R₆, R₇or R₈is each independently a cyanate. In some embodiments, R₁, R₂, R₃, R₄, R₅, R₆, R₇or R₈ is each independently an isocyanate. In some embodiments, R₁, R₂, R₃, R₄, R₅, R₆, R₇or R⁸ is each independently a thiocyanate. In some embodiments, R₁, R₂, R₃, R₄, R₅, R₆, R₇or R₈is each independently an isothiocyanate. In some embodiments, R₁, R₂, R₃, R₄, R₅, R₆, R₇or R₈ is each independently a mesylate. In some embodiments, R₁, R₂, R₃, R₄, R₅, R₆, R₇or R₈ is each independently a tosylate. In some embodiments, R₁, R₂, R₃, R₄, R₅, R₆, R₇or R₈ is each independently a triflate. In some embodiments, R₁, R₂, R₃, R₄, R₅, R₆, R₇or R₈ is not SO₂H.

In one embodiment, the hybrid provided herein comprises a carbon nanotube and an anthraquinone, salt thereof or derivative thereof. In one embodiment, the anthraquinone derivative is a dihydroxy or a trihydroxy anthraquinone. In another embodiment, the anthraquinone derivative is purpurin or alizarin. In other embodiments, the carbon nanotube is a single-walled carbon nanotube. In other embodiments, the carbon nanotube is a multi-walled carbon nanotube.

In some embodiments, the hybrid provided herein comprises a carbon nanotube and an acridine, salt thereof or derivatives thereof. In one embodiment, the acridine derivative is acridine orange. In other embodiments, the carbon nanotube is a single-walled carbon nanotube. In other embodiments, the carbon nanotube is a multi-walled carbon nanotube.

In some embodiments, the hybrid provided herein comprises a carbon nanotube and a naphthalene disulfonic acid, salt thereof or derivative thereof. In one embodiment, the naphthalene disulfonic acid derivative salt is selected from the group consisting of chromatropic acid disodium salt, 2,6-naphthalenedisulfonic acid sodium salt, 2,7-naphthalenedisulfonic acid sodium salt, 2-(4-nitrophenylazo) chromotropic acid disodium salt (Chromotrope 2B), tetrasodium 4-amino-5-hydroxy-3,6-bis [[4-[2-(sulphonatooxy) cthyl] sulphonyl] phenylJazo] naphthalene-2,7-disulphonate (Reactive Black 5), and any combination thereof. In other embodiments, the carbon nanotube is a single-walled carbon nanotube. In other embodiments, the carbon nanotube is a multi-walled carbon nanotube.

In some embodiments, the hybrid provided herein comprises a carbon nanotube and a caffeic acid, salt thereof or derivative thereof. In other embodiments, the caffeic acid derivative comprises a caffeic ester or a caffeic amide. In other embodiments, the carbon nanotube is a single-walled carbon nanotube. In other embodiments, the carbon nanotube is a multi-walled carbon nanotube.

In some embodiments, the hybrid provided herein comprises a carbon nanotube and a phenazine, salt thereof or derivative thereof. In other embodiments, the carbon nanotube is a single-walled carbon nanotube. In other embodiments, the carbon nanotube is a multi-walled carbon nanotube.

In some embodiments, the hybrid provided herein comprises a carbon nanotube and an indigo, salt thereof or derivative thereof. In other embodiment, the indigo derivative comprises indigo carmine. In other embodiments, the carbon nanotube is a single-walled carbon nanotube. In other embodiments, the carbon nanotube is a multi-walled carbon nanotube.

In some embodiments, the hybrid provided herein comprises a carbon nanotube and a rhodamine, salt thereof or derivative thereof. In other embodiment, the indigo derivative comprises rhodamine 101 inner salt. In other embodiments, the carbon nanotube is a single-walled carbon nanotube. In other embodiments, the carbon nanotube is a multi-walled carbon nanotube.

In some embodiments, the hybrid provided herein comprises a carbon nanotube and a phenothiazine, salt thereof or derivatives thereof. In other embodiment, the phenothiazine derivative comprises methylene blue. In other embodiments, the carbon nanotube is a single-walled carbon nanotube. In other embodiments, the carbon nanotube is a multi-walled carbon nanotube.

In some embodiments, the hybrid provided herein comprises a carbon nanotube and a thymolphthalein, salt thereof or derivatives thereof. In other embodiments, the carbon nanotube is a single-walled carbon nanotube. In other embodiments, the carbon nanotube is a multi-walled carbon nanotube.

In some embodiments, the hybrid provided herein comprises a carbon nanotube and an aramid nanofiber (ANF). Kevlar is a well-known ultrastrong para-aramid synthetic fiber with a high tensile strength-to weight ratio. The Kevlar fibers can be fragmented into low molecular weight chains and dissolved to form aramid nanofiber (ANF) solution, using DMSO and KOH as first shown by Kotov et al [Yang et al., “Dispersions of aramid nanofibers: A new nanoscale building block,” ACS Nano, vol. 5, no. 9, pp. 6945-6954, 2011]. In other embodiments, the carbon nanotube is a single-walled carbon nanotube. In other embodiments, the carbon nanotube is a multi-walled carbon nanotube.

In some embodiments ANF is added to SWCNTs dispersion following vacuum filtration to obtain SWCNTs-ANF hybrid with improved mechanical properties.

In one embodiment, this invention provides a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salts thereof and their derivative thereof. In another embodiment, the hybrid comprises two, three, four or more different aromatic compounds within the hybrid.

In some embodiments the hybrid provided herein consists essentially of a CNT and an aromatic compound, salt thereof or derivative thereof. In some embodiments the hybrid provided herein consists essentially of a CNT and at least one aromatic compound, salt thereof or derivative thereof. In some embodiments the hybrid provided herein consists essentially of a CNT and at least one aromatic compound, salt thereof or derivative thereof, wherein the hybriddoes not comprise a dispersant.

In some embodiments. provided herein a noncovalent hybrid consisting essentially of a single-walled carbon nanotube (CNT) and at least one aromatic compound. wherein the aromatic compound is selected from the group consisting of anthraquinone. acridine. caffeic acid. phenazine. thymolphthalein. aramid nanofiber (ANF). their salt thereof and their derivative thereof.

A noncovalent hybrid consisting essentially of a multi-walled carbon nanotube (CNT) and at least one aromatic compound. wherein the aromatic compound is selected from the group consisting of anthraquinone. caffeic acid. safranin. thymolphthalein. aramid nanofiber. their salt thereof and their derivative thereof.

In some embodiments, the hybrid provided herein comprises at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof. In other embodiments, the term “derivative thereof” comprises a chemical modification of any one of the listed aromatic compounds with one or more functional groups or with any chemical group (i.e, hydroxyl, alkyl, aryl, halide, nitro, amine, ester, amide, carboxylic acid or combination thereof). For example, by derivatizing anthraquinone with hydroxyl groups (alizarin, purpurin) a hydrophilic hybrid is obtained. By derivatizing anthraquinone with hydrophobic groups (C₆-C₁₀ alkyls), a hydrophobic hybrid is obtained.

In some embodiments, the hybrid provided herein comprises at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof. In other embodiments, the salts of any one of the listed aromatic compounds is an organic or inorganic acid salt or an organic or inorganic basic salt.

Suitable acid salts comprising an inorganic acid or an organic acid. In one embodiment, examples of inorganic acid salts are bisulfates, borates, bromides, chlorides, hemisulfates, hydrobromates, hydrochlorates, 2-hydroxyethylsulfonates (hydroxyethanesulfonates), iodates, iodides, isothionates, nitrate, persulfates, phosphate, sulfates, sulfamates, sulfanilates, sulfonic acids (alkylsulfonates, arylsulfonates, halogen substituted alkylsulfonates, halogen substituted arylsulfonates), sulfonates and thiocyanates.

In one embodiment, examples of organic acid salts may be selected from aliphatic, cycloaliphatic, aromatic, araliphatic, heterocyclic, carboxylic and sulfonic classes of organic acids, examples of which are acetates, arginines, aspartates, ascorbates, adipates, anthranilate, algenate, alkane carboxylates, substituted alkane carboxylates, alginates, benzenesulfonates, benzoates, bisulfates, butyrates, bicarbonates, bitartrates, carboxilate, citrates, camphorates, camphorsulfonates, cyclohexylsulfamates, cyclopentanepropionates, calcium edetates, camsylates, carbonates, clavulanates, cinnamates, dicarboxylates, digluconates, dodecylsulfonates, dihydrochlorides, decanoates, enanthuates, ethanesulfonates, edetates, edisylates, estolates, esylates, fumarates, formates, fluorides, galacturonate gluconates, glutamates, glycolates, glucorate, glucoheptanoates, glycerophosphates, gluceptates, glycollylarsanilates, glutarates, glutamate, heptanoates, hexanoates, hydroxymalcates, hydroxycarboxlic acids, hexylresorcinates, hydroxybenzoates, hydroxynaphthoate, hydrofluorate, lactates, lactobionates, laurates, malates, maleates, methylenebis (beta-oxynaphthoate), malonates, mandelates, mesylates, methane sulfonates, methylbromides, methylnitrates, methylsulfonates, monopotassium maleates, mucates, monocarboxylates, mitrates, naphthalenesulfonates, 2-naphthalenesulfonates, nicotinates, napsylates, N-methylglucamines, oxalates, octanoates, olcates, pamoates, phenylacetates, picrates, phenylbenzoates, pivalates, propionates, phthalates, phenylacetate, pectinates, phenylpropionates, palmitates, pantothenates, polygalacturates, pyruvates, quinates, salicylates, succinates, stearates, sulfanilate, subacetates, tartarates, theophyllineacetates, p-toluenesulfonates (tosylates), trifluoroacetates, terephthalates, tannates, teoclates, trihaloacetates, triethiodide, tricarboxylates, undecanoates and valerates.

In one embodiment, examples of inorganic basic salts may be selected from ammonium, alkali metals to include lithium, sodium, potassium, cesium; alkaline carth metals to include calcium, magnesium, aluminium; zinc, barium, cholines, quaternary ammoniums.

In another embodiment, examples of organic basic salts may be selected from arginine, organic amines to include aliphatic organic amines, alicyclic organic amines, aromatic organic amines, benzathines, t-butylamines, benethamines (N-benzylphencthylamine), dicyclohexylamines, dimethylamines, diethanolamines, ethanolamines, ethylenediamines, hydrabamines, imidazoles, lysines, methylamines, meglamines, N-methyl-D-glucamines, N,N′-dibenzylethylenediamines, nicotinamides, organic amines, ornithines, pyridines, picolies, piperazines, procain, tris (hydroxymethyl) methylamines, tricthylamines, triethanolamines, trimethylamines, tromethamines and urcas.

An “alkyl” group refers, in one embodiment, to a saturated aliphatic hydrocarbon, including straight-chain, branched-chain and cyclic alkyl groups. In one embodiment, the alkyl group has 1-12 carbons. In another embodiment, the alkyl group has 1-7 carbons. In another embodiment, the alkyl group has 1-6 carbons. In another embodiment, the alkyl group has 6-12 carbons. In another embodiment, the alkyl group has 8-12 carbons. In another embodiment, the alkyl group has 1-4 carbons. The alkyl group may be unsubstituted or substituted by one or more groups selected from halogen, hydroxy, alkoxy carbonyl, amido, alkylamido, dialkylamido, nitro, amino, alkylamino, dialkylamino, carboxyl, thio and thioalkyl.

An “alkenyl” group refers, in another embodiment, to an unsaturated hydrocarbon, including straight chain, branched chain and cyclic groups having one or more double bond. The alkenyl group may have one double bond, two double bonds, three double bonds etc. Examples of alkenyl groups are cthenyl, propenyl, butenyl, cyclohexenyl etc. The alkenyl group may be unsubstituted or substituted by one or more groups selected from halogen, hydroxy, alkoxy carbonyl, amido, alkylamido, dialkylamido, nitro, amino, alkylamino, dialkylamino, carboxyl, thio and thioalkyl.

A “haloalkyl” group refers to an alkyl group as defined above, which is substituted by one or more halogen atoms, in one embodiment by F, in another embodiment by Cl, in another embodiment by Br, in another embodiment by I.

An “aryl” group refers to an aromatic group having at least one carbocyclic aromatic group or heterocyclic aromatic group, which may be unsubstituted or substituted by one or more groups selected from halogen, haloalkyl, hydroxy, alkoxy carbonyl, amido, alkylamido, dialkylamido, nitro, amino, alkylamino, dialkylamino, carboxy or thio or thioalkyl. Nonlimiting examples of aryl rings are phenyl, naphthyl, pyranyl, pyrrolyl, pyrazinyl, pyrimidinyl, pyrazolyl, pyridinyl, furanyl, thiophenyl, thiazolyl, imidazolyl, isoxazolyl, and the like. In one embodiment, the aryl group is a 1-12 membered ring. In another embodiment, the aryl group is a 1-8 membered ring. In another embodiment, the aryl group comprises of 1-4 fused rings.

In some embodiments, the invention is directed to noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof.

In other embodiments, the carbon nanotube is a single-walled carbon nanotube (SWCNT). In other embodiments, the carbon nanotube is a (6,5)-single walled carbon nanotube. In other embodiments, the carbon nanotube is a multi-walled carbon nanotube (MWCNT). In other embodiments, the carbon nanotube is a combination of a multi-walled carbon nanotube (MWCNT) and a single walled carbon nanotube (SWCNT).

“Carbon nanotubes,” refers herein to sheets of graphene that form tubes.

“Single-walled nanotube,” as defined herein, refers to a nanotube that does not contain another nanotube.

“Multi-walled carbon nanotube,” refers herein to more than one nanotube within nanotubes (including for example double walled nanotube).

In some embodiments, the hybrid of this invention comprises between 5 wt % to 95 wt % of carbon nanotube (CNT). In other embodiments, the hybrid composition comprises between 30 wt % to 95 wt % of carbon nanotube (CNT). In other embodiments, the hybrid composition comprises between 50 wt % to 95 wt % of carbon nanotube (CNT). In other embodiments, the hybrid composition comprises between 70 wt % to 95 wt % of carbon nanotube (CNT). In other embodiments, the hybrid composition comprises between 5 wt % to 80 wt % of carbon nanotube (CNT). In other embodiments, the hybrid composition comprises between 5 wt % to 75 wt % of carbon nanotube (CNT). In other embodiments, the hybrid composition comprises between 5 wt % to 70 wt % of carbon nanotube (CNT). In other embodiments, the hybrid composition comprises between 5 wt % to 40 wt % of carbon nanotube (CNT). In other embodiments, the hybrid composition comprises between 5 wt % to 10 wt % of carbon nanotube (CNT). In other embodiments, the hybrid composition comprises between 5 wt % to 15 wt % of carbon nanotube (CNT). In other embodiments, the hybrid composition comprises between 10 wt % to 30 wt % of carbon nanotube (CNT). In other embodiments, the hybrid composition comprises between 5 wt % to 20 wt % of carbon nanotube (CNT). In other embodiments, the hybrid composition comprises between 15 wt % to 60 wt % of carbon nanotube (CNT). In other embodiments, the hybrid composition comprises between 20 wt % to 70 wt % of carbon nanotube (CNT). In other embodiments, the hybrid composition comprises between 35 wt % to 75 wt % of carbon nanotube (CNT). In other embodiments, the hybrid composition comprises between 65 wt % to 70 wt % of carbon nanotube (CNT).

In some embodiments, the hybrid comprises purpurin and SWCNT. In other embodiment, the hybrid comprises a 1:1 weight ratio of the purpurin and the SWCNT, respectively. In other embodiment, the hybrid comprises a 1:95 to 95:1 weight ratio of the purpurin and the SWCNT, respectively. In other embodiment, the hybrid comprises a 1:95 to 50:50 weight ratio of the purpurin and the SWCNT, respectively. In other embodiment, the hybrid comprises a 1:1. 1:10, 1:20, 1:30 1:50; 1:70, 1:95 weight ratio of the purpurin and the SWCNT, respectively.

In some embodiments, the hybrid comprises alizarin and SWCNT. In other embodiment, the hybrid comprises a 1:1 weight ratio of the alizarin and the SWCNT respectively. In other embodiment, the hybrid comprises a 1:95 to 95:1 weight ratio of the alizarin and the SWCNT, respectively. In other embodiment, the hybrid comprises a 1:95 to 50:50 weight ratio of the alizarin and the SWCNT, respectively. In other embodiment, the hybrid comprises a 1:1, 1:10, 1:20, 1:30 1:50; 1:70, 1:95 weight ratio of the alizarin and the SWCNT, respectively.

In some embodiments, the hybrid comprises purpurin and MWCNT. In other embodiment, the hybrid comprises a 1:1 weight ratio of the purpurin and the MWCNT. In other embodiment, the hybrid comprises a 1:95 to 95:1 weight ratio of the purpurin and the MWCNT. respectively. In other embodiment, the hybrid comprises a 1:95 to 50:50 weight ratio of the purpurin and the MWCNT, respectively. In other embodiment, the hybrid comprises a 1:1, 1:10, 1:20. 1:30 1:50; 1:70, 1:95 weight ratio of the purpurin and the MWCNT, respectively.

In some embodiments, the hybrid comprises alizarin and MWCNT. In other embodiment, the hybrid comprises a 1:1 weight ratio of the alizarin and the MWCNT, respectively. In other embodiment, the hybrid comprises a 1:95 to 95:1 weight ratio of the alizarin and the MWCNT, respectively. In other embodiment, the hybrid comprises a 1:95 to 50:50 weight ratio of the alizarin and the MWCNT, respectively. In other embodiment, the hybrid comprises a 1:1, 1:10. 1:20, 1:30 1:50; 1:70, 1:95 weight ratio of the alizarin and the MWCNT, respectively.

In some embodiments, the hybrid comprises aramid nanofilber (ANF) and SWCNT. In other embodiment, the hybrid comprises a 1:1 weight ratio of the aramid nanofilber (ANF) and the SWCNT, respectively. In other embodiment, the hybrid comprises a 1:95 to 95:1 weight ratio of the aramid nanofilber (ANF) and the SWCNT, respectively. In other embodiment, the hybrid comprises a 1:95 to 50:50 weight ratio of the aramid nanofilber (ANF) and the SWCNT. respectively. In other embodiment, the hybrid comprises a 1:1, 1:10, 1:20, 1:30 1:50; 1:70, 1:95 weight ratio of the aramid nanofilber (ANF) and the SWCNT, respectively.

In some embodiments, the hybrid comprises aramid nanofilber (ANF) and MWCNT. In other embodiment, the hybrid comprises a 1:1 weight ratio of the aramid nanofilber (ANF) and the MWCNT, respectively. In other embodiment, the hybrid comprises a 1:95 to 95:1 weight ratio of the aramid nanofilber (ANF) and the MWCNT, respectively. In other embodiment, the hybrid comprises a 1:95 to 50:50 weight ratio of the aramid nanofilber (ANF) and the MWCNT, respectively. In other embodiment, the hybrid comprises a 1:1, 1:10, 1:20, 1:30 1:50; 1:70, 1:95 weight ratio of the aramid nanofilber (ANF) and the MWCNT, respectively.

In some embodiments, the hybrid provided herein is in a form of a dispersion, buckypapers, a coating, a bulk material, paste, a powder or an aerogel. In other embodiments, the hybrid provided herein is a dispersion in an organic or aqueous solvent. In other embodiments, the hybrid provided herein is a buckypaper or a film. In other embodiments, the hybrid provided herein is used as coating. In other embodiments, the hybrid provided herein is a powder. In other embodiments, the hybrid provided herein is a coating. In other embodiments, the hybrid provided herein is a paste. In other embodiments, the hybrid provided herein is an aerogel. In other embodiments, the coating is a powder coating.

In some embodiments, the hybrid provided herein is conductive.

In some embodiments, the hybrid provided herein is hydrophilic.

A “bulk material” refers herein to a material where the hybrid is dispersed in it in 3D.

### Process for the Preparation of Noncovalent Hybrids

In some embodiments, this invention provides a process for the preparation of noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof; the process comprises:
optionally grinding the carbon nanotube; and
mixing the carbon nanotube and the at least one aromatic compound in a sonication bath in an aqueous solvent, an organic solvent, or combination thereof and sonicated for a period of time to obtain a dispersion comprising the hybrid.

In some embodiments, this invention provides a process for the preparation of noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof; the process comprises:
grinding the carbon nanotube; and
mixing the carbon nanotube and the at least one aromatic compound in a sonication bath in an aqueous solvent, an organic solvent, or combination thereof and sonicated for a period of time to obtain a dispersion comprising the hybrid.

In some embodiments, the mixing step in the sonication bath is for a period of sonication ranging between 15 min to one hour.

In another embodiment the grinding/milling is performed in a solid grinder at between 50-100 krpm for a period of between 2 minutes to 1 hour. In another embodiment, the grinding/milling is performed for a period of between 2 minutes to 10 minutes. The term grinding and milling are used herein interchangeably.

In some embodiments, the process for the preparation of the hybrid of this invention is further purified by centrifugation, filtration, or precipitation to yield homogeneous hybrid.

In some embodiment, the organic solvent used in the preparation of the hybrid is chloroform, methylene chloride, carbon tetrachloride dichloroethane, glyme, diglyme, triglyme, tricthylene glycol, trichloroethane, tertbutyl methyl ether, tetrachloro ethane, acetone, THF, DMSO, toluene, benzene, alcohol, isopropyl alcohol (IPA), chlorobenzene, acetonitrile, dioxane, ether, NMP, DME, DMF, ethyl-acetate or combination thereof. Each represents a separate embodiment of this invention.

The process for the preparation of the hybrids provided herein comprises a sonication step. The sonication, mechanically and chemically altered CNTs in solution. Bath sonication of CNTs in the presence of an aromatic molecules in a preferred solvent disperses the CNTs in a way that enables improved processing by spray-coating, filtration, casting and bulk composite applications.

In some embodiments, the hybrid prepared by the process provided herein has improved spraying, filtration, or printing properties compared to carbon nanotubes (not hybrids). In some embodiments, the hybrid prepared by the process provided herein has improved spraying, filtration, or printing properties compared to hybrids, where the carbon nanotube was not milled/grinded prior to mixing with an aromatic compound.

The aromatic compounds within the hybrids provided herein, modify the surface energy of the adsorbing nanotubes for better solution dispersibility and adhesion.

Composite comprising the noncovalent hybrid provided herein and uses thereof.

Both SWCNT and MWCNT have similar uses as adsorptive materials, conductive fibers, sheets and fabrics, porous electrodes, coatings or membranes, conductive inks, conductive and/or reinforcing additives to material composites, and part of electro-sensing, electro-catalytic or photovoltaic systems. They differ by porosity, electrical and thermal conductivity; chemical, thermal and photonic stability; surface energy; chemical adsorptivity; tensile strength and more. Their specific use may be tailored to a specific application using the hybrids provided herein.

In some embodiments, this invention provides a composite comprising a polymer and a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof, wherein the composite has improved mechanical and/or conductivity compared to CNT alone (i.e. not a hybrid). In other embodiments, the carbon nanotube is a single-walled carbon nanotube. In other embodiments, the carbon nanotube is a multi-walled carbon nanotube.

In other embodiments, the polymer is any known organic polymer with melting point higher than 25° C. In other embodiments, the polymers comprise polyethylene, polypropylene, ABS, nylons, polystyrene, polyvinyl chloride, polylactic acid, polyurethanes, polyester, epoxy resin, poly acrylates, PEEK and more (e.g. any polymer that can be used in a 3D printer) and their combination and/or copolymers.

In some embodiments, this invention provides a porous electrode for electrochemical application, comprising a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof. In other embodiments, the electrochemical application comprises circular voltammetry, a sensor, an energy storage, and an energy conversion. In other embodiments, the carbon nanotube is a single-walled carbon nanotube. In other embodiments, the carbon nanotube is a multi-walled carbon nanotube.

In some embodiments, the hybrid provided herein is used for the preparation of electrodes. In other embodiments, the hybrid provided herein is used for the preparation of porous electrodes. In other embodiments, the hybrid provided herein is used for the preparation of transparent electrodes.

In one embodiment, the electrode comprises the hybrid provided herein and/or nanoparticles and/or polymers in a way that will enable appropriate surface energy, selectivity, surface area, porosity, and chemical and thermal stability needed for their utilization in the mentioned systems.

In some embodiments, this invention provides a stretchable, flexible and/or inflatable material comprising a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof. In another embodiments, the hybrid is conductive, and the conductivity of the hybrid is maintained upon stretching or inflation of the material. In other embodiments, the material is coated by the hybrid. In other embodiments, the hybrid is embedded within the material. In other embodiments, the hybrid is a coating on the surface of the material. In other embodiments, the carbon nanotube is a single-walled carbon nanotube. In other embodiments, the carbon nanotube is a multi-walled carbon nanotube.

In other embodiments, the stretchable, flexible and/or inflatable material a fabric, a stretchable textile, a paper, or an elastomer (e.g. latex, rubber, polyurethane, silicone). In other embodiments, the elastomer is latex, rubber, polyurethane or silicone.

In some embodiments, this invention provides an EMI (electromagnetic interference) shielding and electromagnetic radiation absorbers comprising a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof. In other embodiments, the electrochemical application comprises circular voltammetry, a sensor, an energy storage, and an energy conversion, wherein the hybrid is conductive in the infrared and microwave ranges. The EMI shielding or the electromagnetic radiation absorbers are made of conductive CNT hybrid. EMI shields are faraday cages constructed around a device or an object needed to be shielded from EMI. In other embodiments, the carbon nanotube is a single-walled carbon nanotube. In other embodiments, the carbon nanotube is a multi-walled carbon nanotube.

In some embodiments, this invention provides a construction material, wherein the construction material comprises a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof, wherein the hybrid reinforces the construction material compared to CNT alone (not a hybrid). In other embodiments, the carbon nanotube is a single-walled carbon nanotube. In other embodiments, the carbon nanotube is a multi-walled carbon nanotube.

In another embodiment, the hybrid provided herein is embedded within the construction material. In another embodiment, the construction material is coated by the hybrid. In other embodiments, the construction material comprises concrete, a gypsum or construction polymers. In other embodiments, the construction polymers comprise polyethylene, polypropylene, ABS, nylons, polystyrene, polyvinyl chloride, polylactic acid, polyurethanes, polyester, epoxy resin, poly acrylates, PEEK and more (e.g. any polymer that can be used in a 3D printer) and their combination and/or copolymers.

In some embodiments, the hybrid provided herein is used for the preparation of construction material.

In other embodiments the hybrid is embedded in glass made by xerogel methods.

In some embodiments, this invention provide a dispersion comprising a noncovalent hybrid comprising a carbon nanotube (CNT) and at least one aromatic compound, wherein the aromatic compound is selected from the group consisting of anthraquinone, acridine, naphthalene disulfonic acid, caffeic acid, phenazine, indigo, rhodamine, phenothiazine, thymolphthalein, aramid nanofilber (ANF) their salt thereof and their derivative thereof in organic or aqueous solvent. In other embodiments, the carbon nanotube is a single-walled carbon nanotube. In other embodiments, the carbon nanotube is a multi-walled carbon nanotube.

In other embodiment, the dispersion dispersibility of CNTs in organic solvents and water is up to 2 g/l.

In other embodiments, the dispersion is filtered on a filter forming a hydrophilic or a hydrophobic buckypaper on the filter. The hydrophobicity or hydrophilicity is determined by the properties of the aromatic compounds within the hybrids. In one embodiment, the buckypaper is hydrophilic and is used for water-oil separation or desiccation. In one embodiment, the buckypaper is hydrophobic and is used for protecting surfaces from humidity and liquid water, water soluble materials (e.g. self-cleaning surfaces), while staying permeable to other gasses or organic liquids. The hydrophobic buckyball can be used also for protecting a substrate from regular organic materials that are not polyhalogenated.

In some embodiments a hybrid dispersion is applied on solid surfaces such as non limiting examples of glass, silicon oxide, PP, PVC, PET and paper by drop casting, dipping, spray coating, filtration, printing or powder coating to form conductive hybrid films on solid surfaces (substrates). In other embodiments the film can be transferred to another solid surface by hot press. In other embodiments, the film is transferred as exemplified in Example 1 and Example 2.

In one embodiment, the terms “a” or “an” as used herein, refer to at least one, or multiples of the indicated element, which may be present in any desired order of magnitude, to suit a particular application, as will be appreciated by the skilled artisan.

The following examples are to be considered merely as illustrative and non-limiting in nature. It will be apparent to one skilled in the art to which the present invention pertains that many modifications, permutations, and variations may be made without departing from the scope of the invention.

### EXAMPLES

### Example 1

A Hybrid of Alizarin and Single Wall Carbon Nano Tube (SWCNT)-Maintaining Conductivity upon Stretch

20 mg of SWCNT (Tuball®) (from a 6 g batch milled for 2 minutes at 77 krpm, concentration of 0.5 g/l) and 20 mg alizarin were mixed in 40 mL isopropyl alcohol (IPA) in a bath-sonicated for 30 min. The dispersion was spray-coated on a 10×21 cm paper sheet in several layers where a heat gun was used to dry each layer. One side of a 20×3 cm commercial two-sided polyurethane gel elastomeric ribbon was taped on the length of the paper. The paper with the tape were passed through a laminator (hot press, at room temperature) in order to apply uniform pressure. Afterwards the tape was detached from the face of the paper sheet, and the CNT hybrid was fully transferred to it. The initial measured resistance from one end to another was 250Ω. The same tape then was stretched to ca. 30 cm, and the obtained measured resistance was 14 kΩ. The tape was additionally stretched to 123 cm and the measured resistance rose to 150 kΩ. Surface fiber alignment by swiping the tape with a finger pressure from end to end (while wearing nitrile rubber gloves) resulted in the 3-fold resistance decrease to 56 kΩ (2 (Table 1). This behavior indicates the characteristic of the hybrid of this invention that maintains conductivity upon stretching the substrate (By changing the average distance between the CNTs, starting with 0.1 mg/cm² then the elastomer was stretched by 600%.).

TABLE 1
Resistance of elastomeric ribbon coated by
hybrid of this invention following stretch.

| Length of polyurethane gel elastomeric ribbon | Resistance | |
|---|---|---|
| 20 cm (initial length) | 250 | Ω |
| 30 cm | 14 | kΩ |
| 123 cm | 150 | kΩ |
| 123 cm after surface fiber alignment | 56 | kΩ |

### Example 2

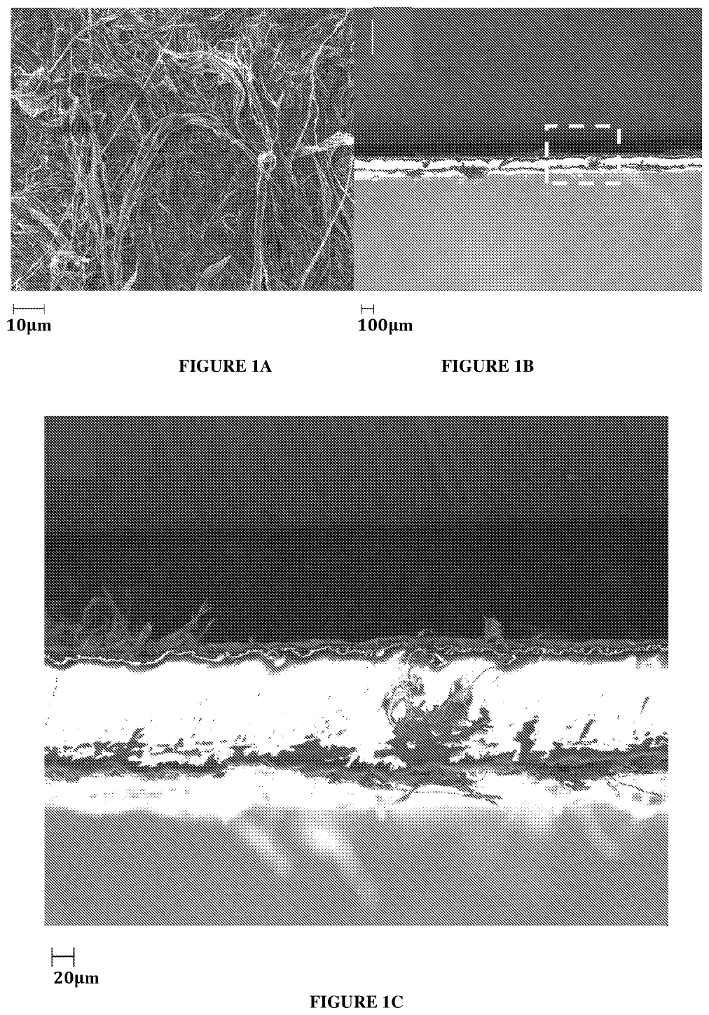

A Hybrid of Alizarin and Single Wall Carbon Nano Tube (SWCNT) on a PE substrate via Transfer of Hybrid Coating Surface (FIGS. 1A-1C).

A paper sheet covered with Tuball®SWCNT-alizarin noncovalent hybrid obtained by the same method as described in Example 1. The paper sheet was folded in two along its width. A 5×5 cm piece of a commercial polyethylene t (PE) sheet (87.5±1 μm thick) was sandwiched between the CNT hybrid-covered face of the paper sandwiched again between two PET sheets (100 μm thick) and passed through a desktop laminator heated to 140° C. (hot roll press), it was repeated 10 times (see Table 2 for thickness of theCNT hybrid-coated paper after thermal laminator treatment). The CNT hybrid was completely transferred to the surfaces of the PE. The conductivity from end to end, after finger pressure strokes (with a gloved hand) all over the surface was measured to be in the range of 60-110Ω.

TABLE 2
Measured thicknesses of components
in the PE composite production.

| [μm] | PE sheet | PEwith CNT hybrid |
|---|---|---|
| Sample 1 | 87.5 ± 1 μm | 107 ± 4 μm |
| Sample 2 | 87.5 ± 1 μm | 106 ± 3 μm |

The paper and the PE covered surfaces can be utilized as pressure sensors when two covered surfaces are laid facing each other. Pressure application on the sheets resulted in resistivity reduction (e.g. 10×5 cm area the resistance went from ca. 300Ω to ca. 250Ω and 215Ω when weights of 340 g and 1200g were put on the device, respectively.

### Example 3

### A Hybrid of Purpurin and Multi Wall Carbon Nano Tube (MWCNT)

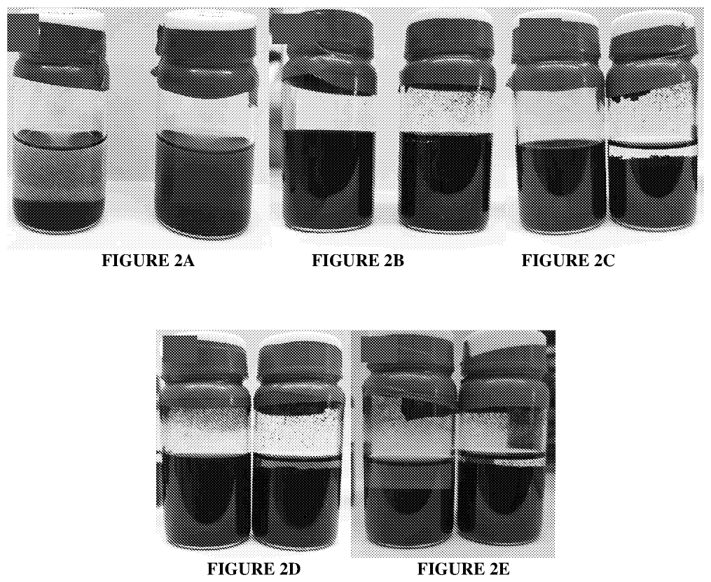

Purpurin and MWCNT (10-20 nm in diameter, 20-30 μm long, from Cheaptubes.com) hybrid noncovalent dispersions were prepared in different solvents (e.g. chloroform, tetrahydrofuran (THF), ethyl acetate (EA), acetone, IPA, acetonitrile (ACN), dimethyl sulfoxide (DMSO) and water (see FIGS. 2A-2E for comparison of MWCNT dispersion in various solvents). In a typical procedure, 12 mg of MWCNT, 6 mg of purpurin and 12 ml of one of the listed solvents were sonicated together for 15 min. The dispersion was stable for at least 14 hours. The MWCNT dispersion then was vacuum-filtrated and washed with the solvent until the washing solvent was clear. The received hybrid on the filter [buckypaper (BP)] was dried at ambient temperature and easily peeled off from the PVDF filter membrane. The obtained BP was highly hydrophilic (very small contact angle of a 100 μl water droplet) and can be used for example for water-oil separation or in desiccation

The obtained BP can be easily redispersed (to a concentration of at least 2 mg/ml) for e.g. in isopropanol or water by bath sonication of several minutes, enabling recyclability.

### Example 4

### A Hybrid of Purpurin and Single Wall Carbon Nano Tube (SWCNT)

Purpurin and SWCNT (Tuball® SWCNT) noncovalent hybrid dispersions were prepared. In a typical procedure 12 mg of SWCNT, 6 mg of purpurin and 12 ml of dichlorobenzene (DCB) were bath-sonicated for 30 min. Then 48 ml of DCB were added and sonicated for 15 min. The SWCNT dispersion was filtered through a syringe needle.

The dispersion was vacuum filtrated and washed with chloroform until the washings were colorless. The received hybrid on the filter (buckypaper, BP) was dried at ambient temperature and easily peeled off from the PVDF filter membrane. The obtained BP is hydrophilic.

### Example 5

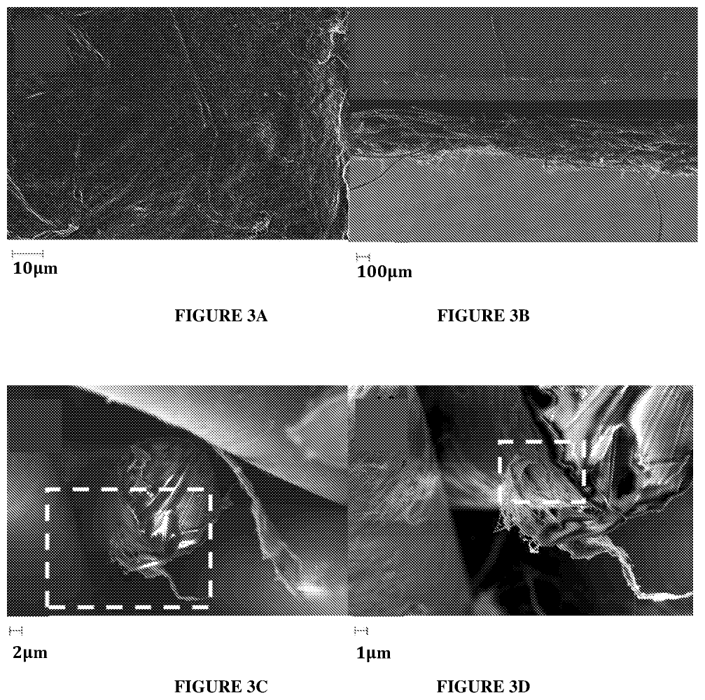

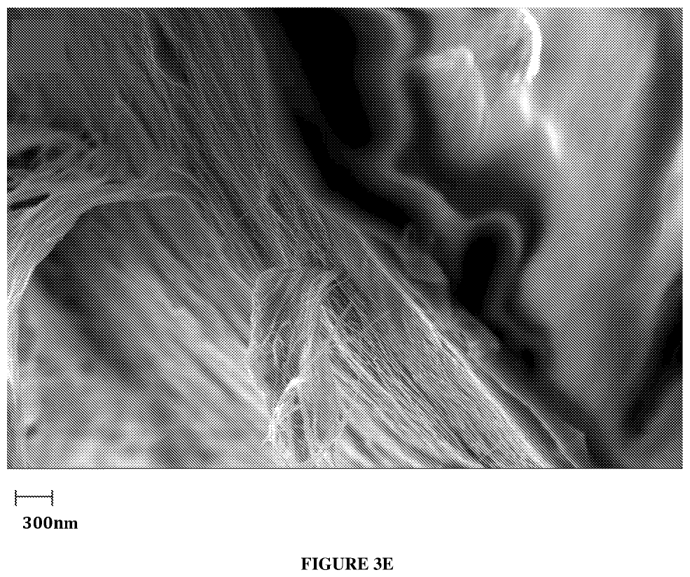

### Non-Woven Polypropylene Fabric Coated by Hybrid of This Invention (FIGS. 3A-3E)

A 10 cm diameter circle was cut out of a non-woven polypropylene (PP) fabric (40 g/m²). The PP circle (310 mg) was placed in vacuum filtration support with the same diameter, and 20 mg of SWCNT (Tuball™) with 20 mg alizarin in 40 ml of isopropyl alcohol was sprayed on it using a spray gun (0.8 mm nozzle at 0.5 bar pressure). After process the PP circle was placed in a 120° C. oven for ca. 5 min. The measured resistance of the diameter of the circle was ca. 400Ω (due to excess of alizarin). In the next step, the SWCNT hybrid covered PP circle was washed with IPA until the washings were practically colorless. The mass added to the PP circle measured after the washing is ca. 10 mg (˜3 w/w %). The PP circle was placed in a 120° C. oven for ca. 5 min. The measured resistance on the covered face on the diameter of the circle was ˜40Ω, while the non-covered face showed irregular conductivity at the range of 1-50*10³Ω. When the process is repeated on the other side, after the additional washing the total added mass is ca 30 mg (˜4.5 w/w %). The best double-sided sample had resistance on the diameter of the circle on both sided ˜15Ω.

### Example 6

### Single Wall Carbon Nanotubes (SWCNTs)-Kevlar ANF Hybrid

### ANFs Solution:

To 200 ml of Dimethyl sulfoxide (DMSO), 1 g of Kevlar (sewing thread, SGT.KNOTS) and 1.5 g KOH was added and stirred (350 rpm) for 7 days at r.t. to give dark red homogenous solution (5 mg/ml). The solution was further diluted with DMSO to 1 mg/ml concentration in order to obtain aramide nanofibers (ANF) solution.

### SWCNTs Grinding

1 g of SWCNTs (Tuball, Ocsial) were dry grinded using grinding machine (HSIANGTAI) for 10 min, cooling to r.t. after each 1 min of grinding.

SWCNT-Kevlar ANF hybrid

6 mg of the grinded SWCNTs were added to 12 ml of DMSO (0.5 mg/ml) in 20 ml vial and bath sonicated for 30 min. To the vial, ANF solution at different % was added and sonicated for another 15 min. The SWCNTs-ANF solution was then vacuum filtrated through PTFE membrane, forming a free-standing film, Buckypaper (BP), and washed with DMSO, DDW, and eventually with EtOH. After the washing, the filter paper with the BP was passed through lamination machine and then dried in oven (120° C.) for 5 min. The dry BP peeled easily from the filter paper.

Table 3 presents the mechanical properties and electrical conductivity of SWCNTs BP.

TABLE 3
Mechanical properties and electrical conductivity of
SWCNTs BP with 50% ANF by weight and without ANFs.

| | | Ultimate | | | |
|---|---|---|---|---|---|
| | Young's | Tensile | Elongation | | |
| | Modulus | Strength | at break | Toughness | Conductivity |
| Sample | (GPa) | (MPa) | (%) | (MPa) | (S/cm) |
| SWCNTs | 0.4 ± 0.075 | 17 ± 2.3 | 5.8 ± 1.2 | 0.52 ± 0.2 | 941 ± 67 |
| with 50% | | | | | |
| ANFs | | | | | |
| SWCNTs | 0.18 ± 0.05 | 3.94 ± 1.33 | 3.01 ± 0.9 | 0.07 ± 0.04 | 1718 ± 166 |
| without | | | | | |
| ANFs | | | | | |

It is appreciated by persons skilled in the art that the present invention is not limited by what has been particularly shown and described hereinabove. Rather the scope of the present invention includes both combinations and sub-combinations of various features described hereinabove as well as variations and modifications. Therefore, the invention is not to be constructed as restricted to the particularly described embodiments, and the scope and concept of the invention will be more readily understood by references to the claims, which follow.

What is claimed is:

1. A noncovalent hybrid consisting essentially of single walled carbon nanotubes (CNTs) and alizarin, purpurin or combination thereof.

2. The hybrid of claim 1, wherein the hybrid is coonductive, or wherein the hybrid is hydrophilic.

3. A coating or a buckypaper comprising the hybrid of claim 1.

4. (canceled)

5. (canceled)

6. (canceled)

7. (canceled)

8. The coating of claim 3, wherein the coating is a powder coating.

9-10. (canceled)

11. A composite comprising a polymer and the hybrid of claim 1, optionally wherein the composite has improved mechanical and/or conductivity properties compared to the CNTs alone.

12. A porous electrode for electrochemical application, comprising the hybrid of claim 1.

13. The porous electrode of claim 12, wherein the electrochemical application comprises circular voltammetry, a sensor, an energy storage, and an energy conversion.

14. A stretchable, flexible and/or inflatable material comprising the hybrid of claim 1, wherein the hybrid is conductive, and the conductivity is maintained upon stretching or inflation of the material.

15. The stretchable, flexible and/or inflatable material of claim 14, wherein the hybrid is embedded within the material, or the hybrid is a coating on the surface of the material.

16. The stretchable, flexible and/or inflatable material of claim 15, wherein the material is a fabric, a paper, a stretchable textile or an elastomer, wherein the elastomer is latex, rubber, polyurethane, or silicone.

17. (canceled)

18. An electromagnetic interference (EMI) shielding and electromagnetic radiation absorbers comprising the hybrid of claim 1, wherein the hybrid is conductive in the infrared and microwave ranges.

19. A construction material comprising the hybrid of claim 1, wherein the hybrid reinforces the construction material.

20. The construction material of claim 19, wherein the construction material comprises concrete, a gypsum or construction polymers and/or wherein the construction polymers comprise polyethylene, polypropylene, ABS, nylons, polystyrene, polyvinyl chloride, polylactic acid, polyurethanes, polyester, epoxy resin, poly acrylates, PEEK and more their combination and/or copolymers.

21-22. (canceled)

23. The hybrid of claim 3, wherein the buckypaper is used for water-oil separation or desiccation.

24. A process for the preparation of a noncovalent hybrid consisting essentially of single walled carbon nanotubes (CNTs) and alizarin, purpurin or combination thereof wherein the process comprises:
optionally grinding the single walled carbon nanotubes; and
mixing the single walled carbon nanotubes and alizarin, purpurin, or combination thereof in a sonication bath in an aqueous solvent, an organic solvent, or combination thereof and sonicated for a period of time to obtain a dispersion comprising the hybrid.

25. (canceled)

26. The process of claim 24, wherein the hybrid is further purified by centrifugation, filtration or precipitation to yield homogeneous hybrid.

27. (canceled)

28. A stretchable, flexible and/or inflatable material comprising a hybrid comprising a CNT and at least one aromatic compound, wherein the aromatic compound is selected from the group consisting of anthraquinone, acridine, caffeic acid, phenazine, thymolphthalein, aramid nanofiber, the salt thereof and the derivative thereof, wherein the hybrid is conductive, and the conductivity is maintained upon stretching or inflation of the material.

29. The stretchable, flexible and/or inflatable material of claim 28, wherein the CNT is a single walled carbon nanotube or multi walled carbon nanotube.

30. The stretchable, flexible and/or inflatable material of claim 28, wherein the anthraquinone derivative is a dihydroxy or trihydroxy anthraquinone.

31. The stretchable, flexible and/or inflatable material of claim 30, wherein the anthraquinone derivative is purpurin or alizarin.
